(19) United States
(12) Patent Application Publication
(10) Pub. No.: US 2015/0088442 A1
(43) Pub. Date: Mar. 26, 2015

(54) SYSTEMS AND METHODS FOR UTILITY USAGE MONITORING AND MANAGEMENT

(71) Applicant: Panduit Corp., Tinley Park, IL (US)

(72) Inventors: Peter Thorburn Kenyon Farrar, Monmouth (GB); Adrian Moruz, Ebbw Vale (GB)

(73) Assignee: Panduit Corp., Tinley Park, IL (US)

(21) Appl. No.: 14/183,696

(22) Filed: Feb. 19, 2014

Related U.S. Application Data
(60) Provisional application No. 61/880,429, filed on Sep. 20, 2013.

(51) Int. Cl. G01R 21/133

(52) U.S. Cl. CPC G01R 21/1333
USPC 702/62

(57) ABSTRACT

According to one aspect, a method of providing utility usage information to a user includes automatically receiving at a host system utility usage data collected by a plurality of utility meters at a user site, processing the received utility usage data, storing the processed utility usage data in a database, and reporting utility usage information based on the utility data, via a reporting interface, based on one or more interactive selections received from a user. The plurality of utility meters includes a plurality of different types of utility meters. The host system is at a location remote from the user site. A first portion of the utility usage data is received via a first communications network and a second portion of the utility usage data is received via a second communications network. The first communications network is different from the second communications network.

### CROSS REFERENCE TO RELATED APPLICATIONS

This application claims the benefit of U.S. Provisional Patent Application No. 61/880,429, filed on Sep. 20, 2013, which is incorporated herein by reference in its entirety.

### FIELD OF THE INVENTION

The present invention relates generally to utility monitoring systems and methods and, in particular, to systems and methods for collecting, processing, and reporting utility usage data monitored by a plurality of utility meters.

### BACKGROUND

Modern society is dependent on the use of utility resources (e.g., electricity, water, natural gas, air, and other industrial gases and fluids) to operate devices and systems in residential, commercial, and industrial environments. As the cost of owning or operating a home or a business is dependent on the use cost of utility resource usage, most users of utility resources desire to receive information regarding their consumption of such utility resources. Conventionally, users are provided with information regarding their consumption of utility resources on a monthly basis and with little detail. As such, it is difficult for users to understand whether they are utilizing utility resources in an efficient manner or how their usage of utility resources may be improved. This leads to waste and unnecessary expense.

### SUMMARY

According to one aspect, a utilities management system for collecting, processing, and reporting utility usage data received from a plurality of utility meters is disclosed. The plurality of utility meters are configured to monitor a utility resource at a user site. The utilities management system includes a first data collection device located remotely relative to the user site. The first data collection device is configured to receive the utility usage data from a first utility meter via a first communications network. The utilities management system also includes a second data collection device located remotely relative to the user site. The second data collection device is configured to receive the utility usage data from a second utility meter via a second communications network. The first communications network is different from the second communications network and the first utility meter is different from the second utility meter. The utilities management system further includes a database communicatively coupled to the first data collection device and the second data collection device. The database is configured to store the utility usage data received from the first data collection device and the second data collection device on a database server at a remote location relative to the user site. The utilities management system also includes a reporting interface configured to permit users to interactively view utility information based on the utility usage data stored in the database.

According to another aspect, a method of providing utility usage information to a user includes automatically receiving at a host system utility usage data collected by a plurality of utility meters at a user site, processing the received utility usage data, storing the processed utility usage data in a database, and reporting utility usage information based on the utility data, via a reporting interface, based on one or more interactive selections received from a user. The plurality of utility meters includes a plurality of different types of utility meters. The host system is at a location remote from the user site. A first portion of the utility usage data is received via a first communications network and a second portion of the utility usage data is received via a second communications network. The first communications network is different from the second communications network.

According to still another aspect, a utilities management system for collecting, processing, and reporting utility usage data received from a plurality of utility meters includes a personnel sensor, a data collection module, a data storage module, and a reporting module. The utility meters are configured to monitor a utility resource at a user site. The personnel sensor is configured to monitor and generate occupancy data based on the presence of personnel at one or more locations within the user site. The data collection module is located remotely relative to the user site. The data collection device is configured to receive the utility usage data from the plurality of utility meters and the occupancy data from the personnel sensor via at least one communications network. The data storage module is communicatively coupled to the data collection module. The data storage module is configured to store the utility usage data and the occupancy data received from the data collection module. The reporting module is configured to permit users to interactively view one or more reports based on the utility usage data and the occupancy data.

The foregoing and additional aspects and embodiments of the present invention will be apparent to those of ordinary skill in the art in view of the detailed description of various embodiments and/or aspects, which is made with reference to the drawings, a brief description of which is provided next.

### BRIEF DESCRIPTION OF THE DRAWINGS

The foregoing and other advantages of the invention will become apparent upon reading the following detailed description and upon reference to the drawings.

FIG. 1 illustrates a functional block diagram of a utility management system according to aspects of the present disclosure.

FIGS. 2A-2E illustrate the utility management system of FIG. 1 for exemplary data collection sub-modules according to aspects of the present disclosure.

FIGS. 3A-3I illustrate screen shots of exemplary reports that can be displayed to a user according to aspects of the present disclosure.

FIGS. 4A-4E illustrate screen shots of exemplary reports that can be displayed to a user according to aspects of the present disclosure.

While the invention is susceptible to various modifications and alternative forms, specific embodiments have been shown by way of example in the drawings and will be described in detail herein. It should be understood, however, that the invention is not intended to be limited to the particular forms disclosed. Rather, the invention is to cover all modifications, equivalents, and alternatives falling within the spirit and scope of the invention.

### DESCRIPTION OF ILLUSTRATIVE EMBODIMENTS

According to aspects of the present disclosure, a utility management system 10 for collecting, processing, and reporting utility usage information at one or more facilities associated with a user(s) is disclosed. The utility management system is advantageously adapted to integrate a wide variety of different utility meters 12 to provide a user with a comprehensive and detailed understanding of utility resource usage by the user. The utility management system 10 thus enables the user to make more informed decisions regarding the operation of its facilities based on utility resource usage.

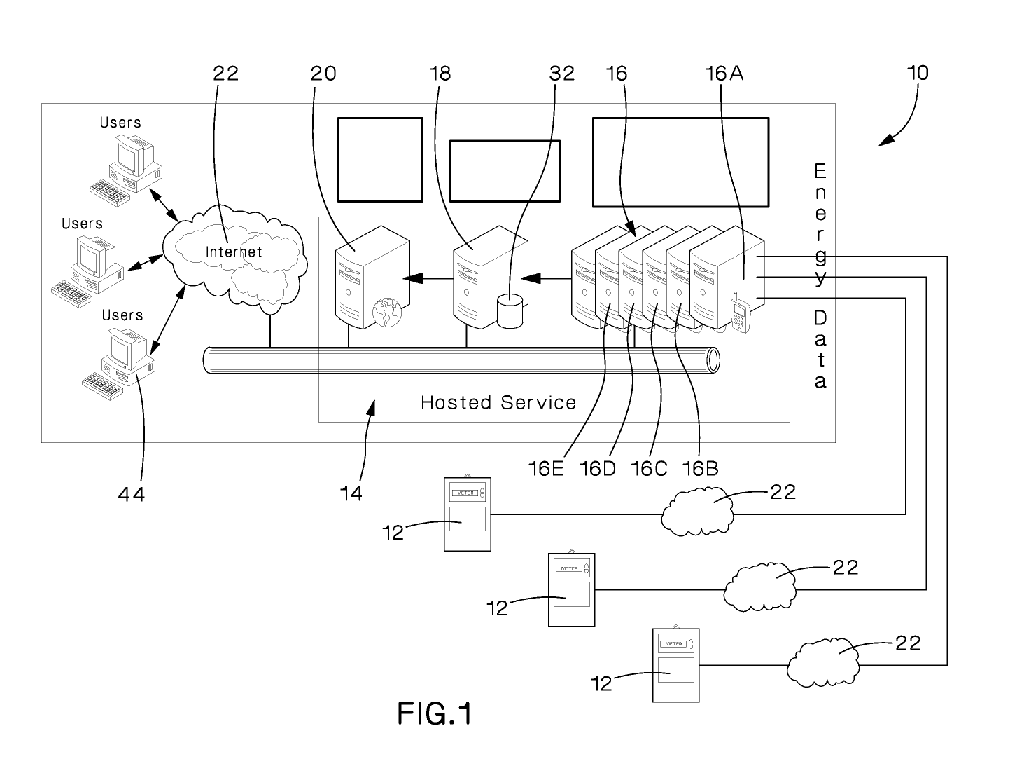

FIG. 1 illustrates a block diagram of an exemplary utility management system 10 for collecting, processing, and reporting data relating to utility resource(s) used at one or more user sites according to aspects of the present disclosure. The utility resource(s) can include water, air, gas, electricity, steam, and/or other industrial fluids or gases, which are consumed and/or utilized by one or more devices at the user site(s).

A plurality of utility meters 12 are provided at the user site(s) to monitor the utility resource(s) that are provided to the devices, systems and subsystems at the user site(s). As used herein, the term “utility meter” is defined to be any device that is configured to monitor at least one utility resource used by an associated device, system, or subsystem, and generate utility usage data relating to such usage of the utility resource(s). For example, in an electrical context, the utility usage data can be indicative of monitored electrical characteristics (e.g., voltage, current, power, harmonics, combinations thereof and/or the like) for a conductor carrying electrical current. As another example, in a water utility resource context, the utility usage data can be a volume per unit of time of water flowing through a pipe. The utility meters 12 can include smart meters, non-smart meters, pulse-output meters, adapters, combinations thereof, and/or the like. The utility meters 12 can be of a variety of different models and types from one or more manufacturers, as described below in greater detail.

The utility management system 10 includes a host system 14 at a host site remotely located relative to the user site(s). The host system 14 has a plurality of operational modules including software, hardware, or a combination thereof for implementing the collecting, processing, and reporting of utility usage data by the utility management system 10. For example, the operational modules 16, 18, 20 can be implemented by one or more controllers (not shown) adapted to perform operations specified by a computer-executable code, which may be stored on a computer readable medium.

The controller(s) can include combinations of operatively coupled hardware components including microprocessors, logical circuitry, communication/networking ports, digital filters, memory, or logical circuitry. The controller(s) can be a programmable processing device, such as an external conventional computer, a server, an on-board field programmable gate array (FPGA) or digital signal processor (DSP) that executes software, or stored instructions. In general, physical processors and/or machines employed by embodiments of the present disclosure for any processing or evaluation may include one or more networked or non-networked general purpose computer systems, servers, microprocessors, field programmable gate arrays (FPGA's), digital signal processors (DSP's), micro-controllers, and the like, programmed according to the teachings of the exemplary embodiments of the present disclosure, as is appreciated by those skilled in the computer and software arts. Appropriate software can be readily prepared by programmers of ordinary skill based on the teachings of the exemplary embodiments, as is appreciated by those skilled in the software art. In addition, the devices and subsystems of the exemplary embodiments can be implemented by the preparation of application-specific integrated circuits or by interconnecting an appropriate network of conventional component circuits, as is appreciated by those skilled in the electrical art(s). Thus, the exemplary embodiments are not limited to any specific combination of hardware circuitry and/or software.

Stored on any one or on a combination of computer readable media, the exemplary embodiments of the present disclosure may include software for controlling the devices and subsystems of the exemplary embodiments, for driving the devices and subsystems of the exemplary embodiments, for enabling the devices and subsystems of the exemplary embodiments to interact with a human user, and the like. Such software can include, but is not limited to, device drivers, firmware, operating systems, development tools, applications software, and the like. Such computer readable media further can include the computer program product of an embodiment of the present disclosure for performing all or a portion (if processing is distributed) of the processing performed in implementations. Computer code devices of the exemplary embodiments of the present disclosure can include any suitable interpretable or executable code mechanism, including but not limited to scripts, interpretable programs, dynamic link libraries (DLLs), Java classes and applets, complete executable programs, and the like. Moreover, parts of the processing of the exemplary embodiments of the present disclosure can be distributed for better performance, reliability, cost, and the like.

Common forms of computer-readable media may include, for example, a floppy disk, a flexible disk, hard disk, magnetic tape, any other suitable magnetic medium, a CD-ROM, CDRW, DVD, any other suitable optical medium, punch cards, paper tape, optical mark sheets, any other suitable physical medium with patterns of holes or other optically recognizable indicia, a RAM, a PROM, an EPROM, a FLASH-EPROM, any other suitable memory chip or cartridge, a carrier wave or any other suitable medium from which a computer can read.

As shown in FIG. 1, the host system 14 includes a data collection module 16, a data storage module 18, and a reporting module 20. The data collection module 16 is operable to receive and, in some instances, process the utility usage data received from the plurality of utility meters 12 over one or more different communications networks 22, using one or more different communications protocols, and/or according to one or more different data formats, as described below. As the plurality of utility meters 12 include meters of different types and configurations, the data collection module 16 includes a plurality of data collection sub-modules 16A-16E that each include different hardware and/or software components correspondingly configured to communicate with each of the different types of utility meters 12. The data storage module 18 is operable to receive and store the utility usage data from the data collection module 16. The reporting module 20 is configured to permit users to interactively view utility information based on the utility data stored by the data storage module 18.

It is often the case that a user may employ a plurality of utility meters 12 at a user site to monitor utility usage associated with a variety of different devices, systems, or subsystems. Significantly, the utility meters 12 at the user site are commonly not all the same type of utility meter 12. In some instances, the user may be monitoring different types of utility resources, which require different types of utility meters 12. For example, a utility meter 12 monitoring electricity at the user site may be different from a utility meter 12 monitoring natural gas usage or a utility meter 12 monitoring water usage at the user site. In other instances, the utility meters 12 at the user site may change over time as older utility meters 12 are replaced, or new equipment requiring metering is added at the user site. The utility meters 12 at a user site can thus have different makes, models, versions, and/or firmware. Additionally, the utility meters 12 can be configured to store utility usage data in different ways (if at all), and/or communicate the utility usage data in different ways. Advantageously, the utility management system 10 of the present disclosure can integrate various different types of utility meters 12 into a unified system for collecting, processing, and reporting utility usage data.

To achieve such advantages, the data collection sub-modules 16A-16E can be configured to receive the utility usage data over a plurality of different communications networks 22 (e.g., wide area networks, public switched networks, telecommunication networks, wireless networks, satellite networks, internet networks, point-to-point networks, etc.), according to a plurality of different communications protocols or standards (e.g., general packet radio services (GPRS), global system for mobile communications (GSM), circuit switched data (CSD), public switched telephone network (PSTN), file transfer protocol (FTP), transmission control protocol/internet protocol (TCP/IP), combinations thereof, and/or the like), and/or using a plurality of different data formats (e.g., device language message specification (DLMS) protocol, comma separated value (CSV) format, etc.). That is, each of the data collection sub-modules 16A-16E can include different hardware and/or software based on the communications network 22, protocol, and/or format by which the utility usage data is received from the utility meters 12.

For example, a data collection sub-module 16A-16E that is configured to receive the utility usage data from a utility meter 12 over a PSTN network can include one or more dial-up modems. As another example, a data collection sub-module 16A-16E that is configured to receive the utility usage data from a utility meter 12 over the internet can include a broadband modem such as, for example, a DSL modem, a cable modem, a satellite dish, a coaxial cable modem, fiber optic components, a wireless transmitter and/or receiver, broadband over powerline (BPL) components, combinations thereof, and/or the like. As yet another example, a data collection sub-module 16A-16E can include an FTP server configured to receive the utility usage data according to a FTP protocol.

According to aspects of the present disclosure, the data collection module 16 can include two or more different data collection sub-modules 16A-16E (i.e., different hardware and/or software configured to receive the utility usage data from different types of utility meters 12 via a different communication network, according to a different communications protocol, and/or according to a different data formatting). In one exemplary implementation, one data collection sub-module 16A can receive the utility usage data generated by a first utility meter(s) 12 over a telephone network while another data collection sub-module 16B can receive the utility usage data generated by a second utility meter(s) 12 over an internet network. In another exemplary implementation, a data collection sub-module 16A can receive the utility usage data generated by a utility meter 12 over a network according to a GSM/CSD protocol while another data collection sub-module 16B can receive the utility usage data generated by another utility meter 12 over a network according to a GSM/GPRS protocol. As yet another exemplary implementation, one data collection sub-module 16A can receive the utility usage data from one utility meter 12 according to a DLMS format while another data collection sub-module 16B receives the utility usage data from another meter according to a CSV format.

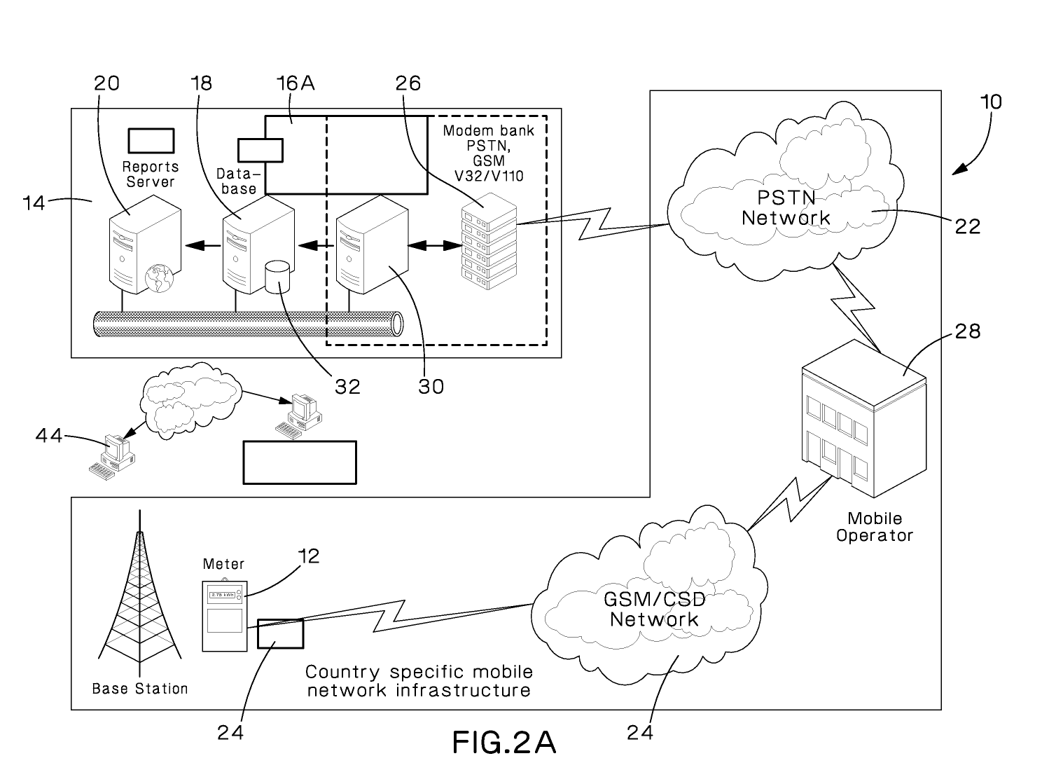

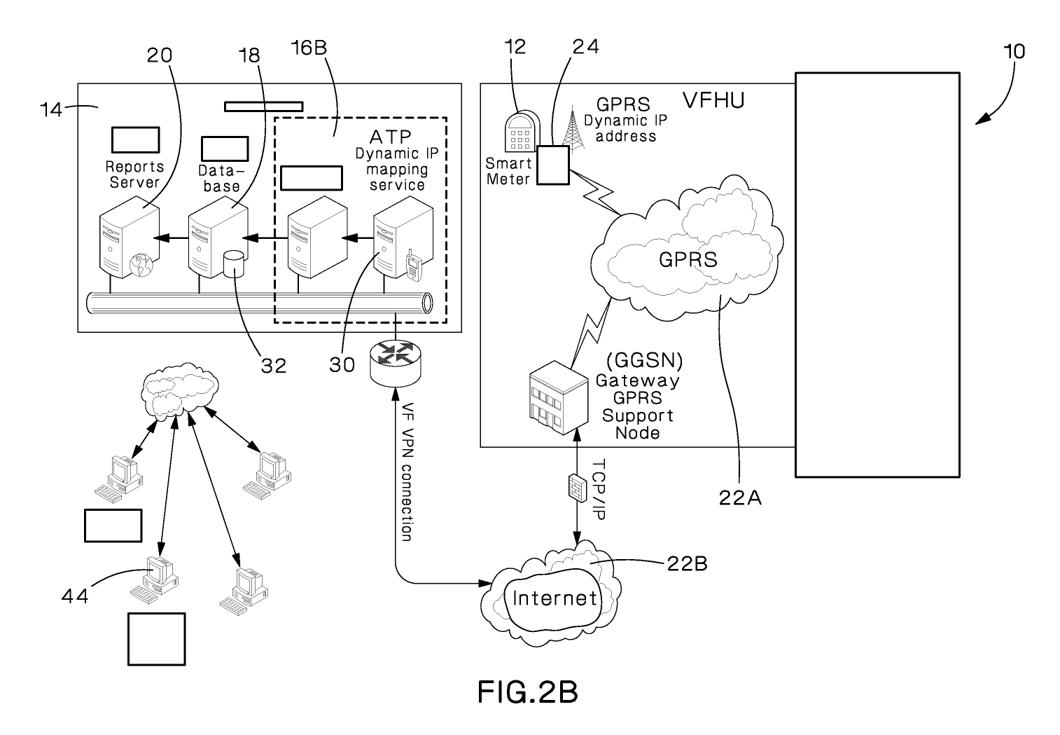

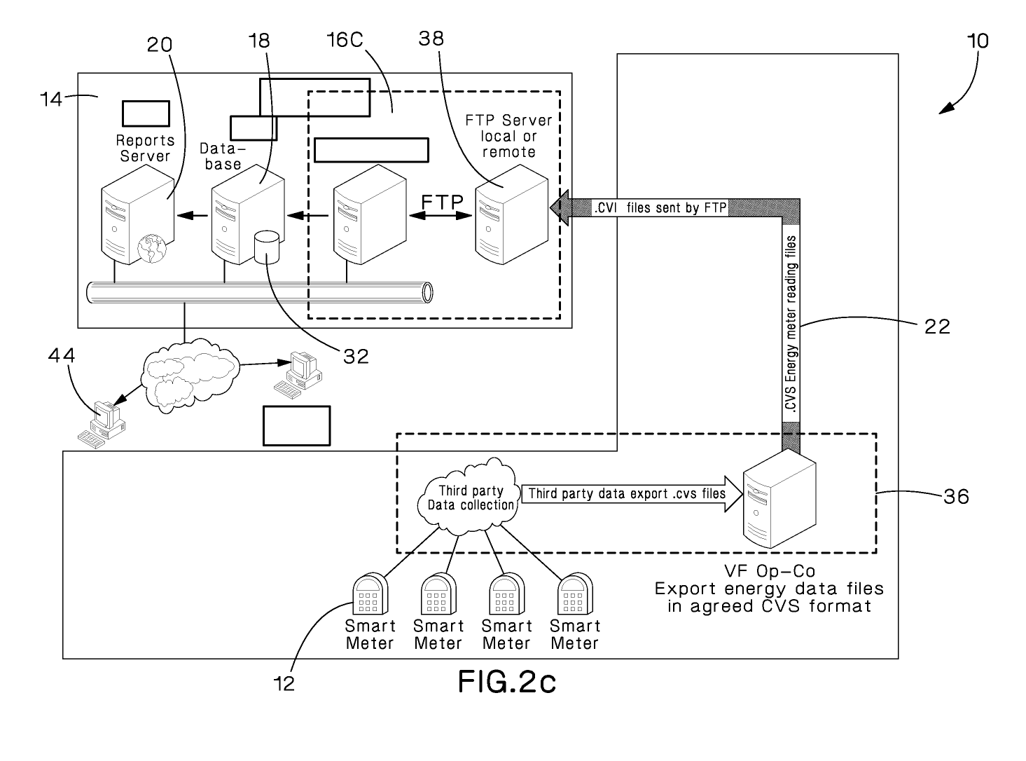

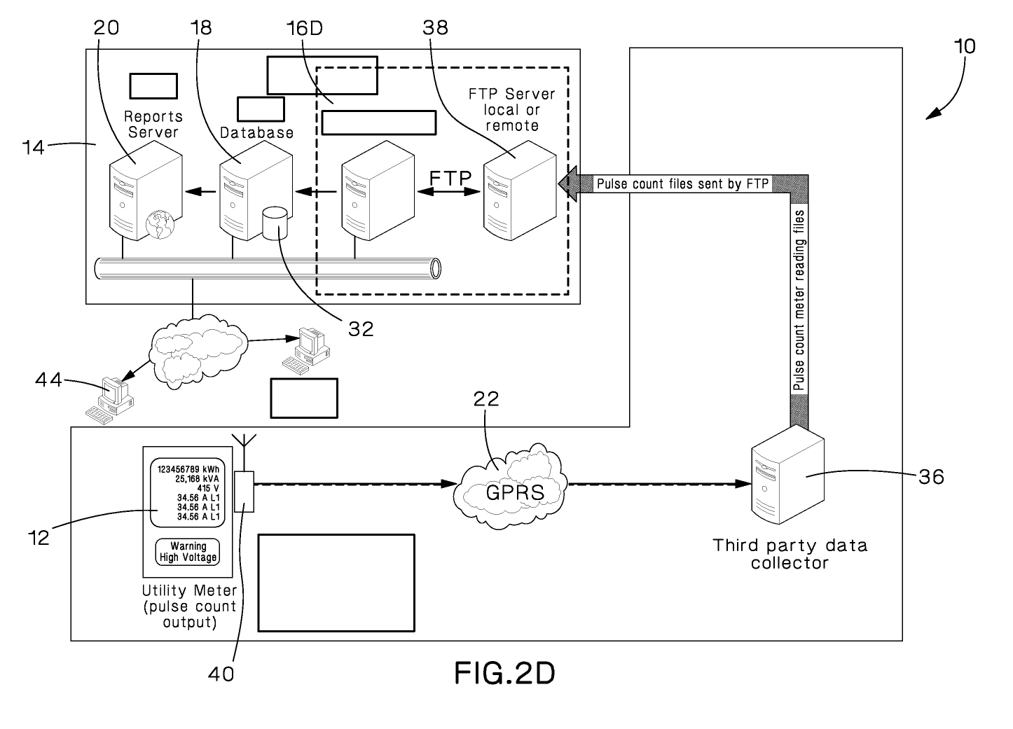

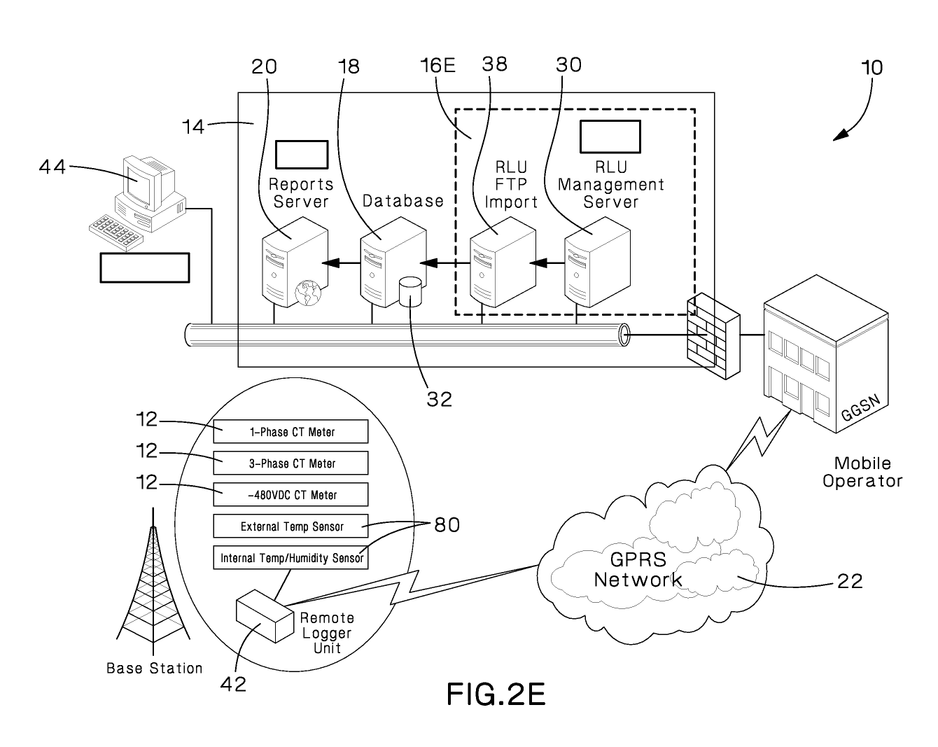

FIGS. 2A-2E illustrate additional non-limiting examples of different data collection sub-modules 16A-16E according to aspects of the present disclosure. It should be understood that the exemplary data collection sub-modules 16A-16E illustrated in FIGS. 2A-2E are provided as examples to further illustrate how diverse types of utility meters 12 can be integrated into the utility management systems 10 of the present disclosure. It should be further understood that the utility management system 10 is not limited to the examples of FIGS. 2A-2E. The utility management system 10 can include all of the data collection sub-modules 16A-16E illustrated and described for FIGS. 2A-2E, some of such sub-modules 16A-16E, and/or alternative data collection sub-modules not illustrated or described for FIGS. 2A-2E.

Referring to FIG. 2A, a block diagram of the utility management system 10 is illustrated for a first exemplary data collection sub-module 16A, which is configured to communicate with a first smart utility meter 12 via a telephone network 22. A smart utility meter is a utility meter 12 that is configured to store the monitored utility usage data in a local memory. The smart meter 12 may also include an electronic controller, such as a microprocessor, for executing firmware or software stored in the local memory of the smart meter 12. To connect the smart meter 12 to the telephone network 22, the first smart meter 12 can include a device modem 24. The device modem 24 can be part of the first smart meter 12 at the time of installation or the first smart meter 12 can be retrofitted with the device modem 24 after installation. The first data collection sub-module 16A correspondingly includes a host modem 26 configured to receive the utility data transmitted by the first smart meter 12 over the telephone network 22.

The configuration of the telephone network 22 may depend on the particular telecommunications infrastructure of the geographic location of the user site and the remote location of the host system 14. According to the non-limiting implementation of FIG. 2A, the device modem 24 can be a dial-up modem configured to connect the first smart meter 12 to a GSM/CSD cellular telephone network and the host modem 26 can be a PSTN modem configured to connect the first data collection sub-module 16A to a PSTN network. The utility usage data can thus be communicated from the first smart meter 12 over the GSM/CSD network to a mobile operator 28 (i.e., a network operator) via the device modem 24 and then communicated from the mobile operator 28 over the PSTN network to the first data collection sub-module 16A via the host modem 26.

While the first smart meter 12 transmits the utility usage data over a GSM/CSD network and the first data collection sub-module 16A receives the utility usage data over a PSTN network in the example illustrated in FIG. 2A, it should be understood that, according to additional and/or alternative implementations, the utility usage data can be transmitted and received over the same communications network 22. For example, the device modem 24 and the host modem 26 can both be GSM/CSD modems such that the first smart meter 12 and the first data collection sub-module 16A both communicate over the GSM/CSD network.

Additionally, it should be understood that, while the device modem 24 and the host modem 26 are configured to communicate over a GSM/CSD network and a PSTN network in FIG. 2A, according to additional and/or alternative examples, the modems 24, 26 can be configured to communicate according to other communication protocols such as, for example, V32/V34 modulation data communications, V110 mode data communications, CDPD, GSM/GPRS, GSM EDGE, UMTS W-CDMA, UMTS HSPA, UMTS TDD, CMDA2000 1xRTT, CDMA2000 EV-DO, GSM EDGE-Evolution, HSPA+, Mobile WiMax, LTE, LTE-Advanced, MBWA, combinations thereof and/or the like.

According to some aspects, the first data collection sub-module 16A can be configured to control the host modems 26 to establish a connection with the device modem 24 and initiate the communication of the utility usage data from the first smart meter 12 to the first data collection sub-module 16A. According to additional and/or alternative aspects, the first smart meter 12 can be configured to automatically initiate the connection and communication of utility usage data to the first data collection sub-module 16A. As one non-limiting example, the utility usage data can be communicated as a serial binary data message of a modulated frequency over the telephone network 22. According to some aspects, the utility usage data can be read by the first smart meter 12 and communicated over the telephone network 22 to the first data collection sub-module 16A according to the DLMS metering information protocol.

While the first data collection sub-module 16A includes one host modem 26 in the example illustrated in FIG. 2A, it should be understood that the first data collection sub-module 16A can include a plurality of host modems 26 to facilitate simultaneously communication between the first data collection sub-module 16A and multiple smart meters 12 at the user site. For example, the plurality of host modems 26 can be directly connected to a server 30 of the host system 14 and/or via a network using a terminal server implementation. The utility usage data received by the first data collection sub-module 16A is subsequently communicated by the data collection module 16 to the data storage module 18 for storage in a database 32, as described in greater detail below.

FIG. 2B illustrates a block diagram of the utility management system 10 for a second exemplary data collection sub-module 16B, which is configured to communicate with a second smart meter 12 via an internet network 22 utilizing a TCP/IP protocol. In the illustrated example, the second smart meter 12 includes a device modem 24 configured to connect the second smart meter 12 to a GSM/GPRS network 22A and the second data collection sub-module 16B includes a server 30 configured to connect to an internet network 22B via a virtual private network (VPN) connection. Also, in the illustrated example, a gateway GPRS support node 34 (GGSN) facilitates the connection and communication between the GSM/GPRS network 22A and the internet network 22B. Thus, in the illustrated example in FIG. 2B, the utility usage data transmitted between the second smart meter 12 and the second data collection sub-module 16B can be adapted for a packet data transmission protocol. The device modem 24 can be part of the second smart meter 12 at the time of installation or the second smart meter 12 can be retrofitted with the device modern 24 after the time of installation.

According to some aspects, the second smart meter 12 can initiate the connection to and communication with the second data collection sub-module 16B. When the second smart meter 12 initiates the GSM/GPRS connection, the GPRS network 22A can allocate an internet protocol (IP) address to the second smart meter. The second smart meter 12 can be configured to retain the IP address for as long as the connection is maintained. If the connection is lost or dropped, then when the connection is reestablished with the GSM/GPRS network 22A, the IP address allocated to the second smart meter 12 may be different. Thus, in effect, the second smart meter 12 can be allocated IP addresses dynamically. The server 30 of the second data collection sub-module 16B may not store the IP addresses of any particular utility meter 12 (e.g., the second smart meter).

According to additional and/or alternative aspects, the second data collection sub-module 16B can initiate the connection to and communication with the second smart meter 12. To allow the second data collection sub-module 16B to poll the second smart meter 12, the server 30 of the second data collection sub-module 16B can be configured as a translation server 30. The translation server 30 is configured to map fixed IP address/port numbers to dynamic IP address/port numbers.

The second smart meter 12 can transmit the utility usage data to the translation server 30 using an optimized protocol such as, for example, over a user datagram protocol (UDP). An optimized protocol can enable the dynamic IP addresses of the second smart meter 12 to be tracked and keep an open channel from the translation server 30 to the second smart meter 12. Additionally, the optimized protocol used by the translation server 30 can be configured to improve efficiency and speed utilizing data packets that have low overhead and low delivery latency for GPRS communications. Thus, if an optimized protocol is utilized, the translation server 30 can verify the data integrity in a more timely and efficient manner than TCP.

According to some aspects, the GSM/GPRS modem 24 of the second smart meter 12 and the translation server 30 can be configured to provide timeouts to ensure continuous operation. Additionally, the second smart meter 12 can periodically or when prompted by the translation server 30, poll in to the translation serve 30 to verify the current IP address and functionality.

While the example illustrated in FIG. 2B includes one second smart meter 12, it should be understood that the second data collection sub-module 16B can be configured to communicate with a plurality of second smart meters 12. For the particular example illustrated in FIG. 2B, when a plurality of second smart meters 12 are employed, each of the second smart meters 12 can transmit to a single IP:port address on the gateway 34. The routing between the user site access point name (APN) termination and the gateway 34 can forward all data to this address to the gateway 34, and all return data to the source address received from the second smart meter 12. Additionally, it is contemplated that, according to some aspects, the plurality of second smart meters 12 each can be uniquely identified by a number derived from at least one of the Integrated Circuit Card Identifier (ICCID) of a physical subscriber identity module (SIM) card, the International Mobile Subscriber Identity (IMSI) stored within the SIM card, or a serial number associated with the second smart meters 12. Further, each SIM number can be mapped 1:1 to a fixed IP:port address for TCP access by the second data collection sub-module 16B. This mapping can be defined in a user configured database used by the translation server 30. A single IP address (user IP) can be used with a different port for each second smart meter 12. Additionally, while the IP addresses are dynamically assigned in FIG. 2B, the second sub-module 16B and the communications networks 22A, 22B can be configured such that the second smart meter 12 has a static IP address.

FIG. 2C illustrates a block diagram of the utility management system 10 for a third exemplary data collection sub-module 16C configured to receive the utility usage data from a third party meter reading entity 36. In some instances, a user may contract out the utility meter reading function to a third party meter reading entity 36. Such companies 36 conventionally visit the user site, read the utility meters 12, and then provide the user with the utility usage data from the meter readings in an electronic format on a periodic basis (e.g., once a month). For example, the third party meter reading entity 36 may provide the utility usage data in a comma separated value (CSV) file format.

Currently, however, such third parties 36 often provide the utility usage data to the users in different file formats and with different parameter fields. According to some aspects of the present disclosure, the third data collection sub-module 16C can be configured to convert a CSV file received from a third party meter reading entity 36 to a standardized CSV file format. According to additional or alternative aspects, the third party 36 can be required to provide the CSV file according to a standardized CSV file format.

According to the non-limiting implementation illustrated in FIG. 2C, the third data collection sub-module 16C can include a file transfer protocol (FTP) server 38 configured to receive the CSV file from the third party meter reading entity 36 over a TCP-based network such as, for example, the internet 22. The third data collection sub-module 16C can be configured to periodically poll the FTP server 38 to check for new CSV files that may have been uploaded by a participating third party meter reading entity 36. If a new file is detected, the third data collection sub-module 16C can read the file from the FTP server 38, parse each line of the data file, and import the data to the data storage module 18. According to an alternative implementation, the third party meter reading entity 36 can automatically transmit new CSV files to the third data collection sub-module 16C when such files are generated by the third party meter reading entity 36. For example, a new CSV file may be generated by the third party meter reading entity 36 daily, weekly, or monthly.

According to some aspects of the present disclosure, the third data collection sub-module 16C can be configured to maintain an audit log of the process of importing the CSV files from the third party meter reading entity 36. For example, the third data collection sub-module 16C can be configured to check for new utility meters 12, missing utility meters 12, invalid data, etc. and log any such events. At the end of the CSV file import process, the third data collection sub-module 16C can be configured to automatically generate a completion report. The third data collection sub-module 16C can be further configured to automatically transmit the completion report to the third party meter reading entity 36 (e.g., via mail, fax, e-mail, SMS, etc.).

FIG. 2D illustrates a block diagram of the utility management system 10 for a fourth exemplary data collection sub-module 16D configured to receive the utility usage data from utility meters 12 that are not smart meters (“non-smart meters”). Non-smart meters 12 can support a pulsed output that can be monitored to generate a pulse count reading. Depending on the type of meter 12 each pulse indicates a unit of measurement. For example, for a non-smart meter 12 monitoring an electrical utility resource, each pulse can be indicative of 0.1 kWh. As another example, for a non-smart meter monitoring a gas utility resource, each pulse can be indicative of 0.01 M³ of gas.

To obtain the utility usage data from such non-smart utility meters 12, an adapter 40 can be coupled to the non-smart utility meter 12. The adapter 40 is configured to detect and count the pulses generated by the non-smart utility meter 12 and communicate the utility usage data to the fourth data collection sub-module 16D in the form of pulse count files. The fourth data collection sub-module 16D can be configured to receive and convert the pulse count files into a format that is consistent with the utility usage data received by other sub-modules 16A-16C, 16E of the data collection module 16.

In the illustrated example, the adapter 40 includes a GSM/GPRS modem for communicating the utility usage data based on the pulse count detected by the adapter 40 to a third party meter reading entity 36 (e.g., via a GSM/GPRS network 22) and the fourth data collection sub-module 16D includes an FTP server 38 for receiving the utility usage data form the third party meter reading entity 36. It should be understood that, according to additional and/or alternative aspects, the adapter 40 and the fourth data collection sub-module 16D can be configured to communicate over other networks 22, according to other communication protocols, and/or using a different data format. For example, according to another non-limiting implementation, the adapter 40 can include a GSM/GPRS modem and the fourth data collection sub-module 16D can include a GSM/GPRS modem for facilitating communication of the utility usage data based on the pulse count detected by the adapter 40 to the fourth data collection sub-module 16D.

In each of the exemplary data collection sub-modules 16A-16C described and illustrated for FIGS. 2A-2C, the first, second and third data-collection sub-modules 16A-16C are configured to receive the utility usage data individually from each of the utility meters 12 associated with the respective data collection sub-modules 16A-16C. That is, for example, if a user site includes a plurality of first smart meters 12 having dial-up modems 24, the first data collection sub-module 16A separately receives utility usage data from each of those smart meters 12 individually.

According to additional and/or alternative aspects of the present disclosure, the utility usage data generated by a plurality of utility meters 12 can be aggregated at the user site and collectively communicated to a fifth exemplary data collection sub-module 16E at one time. In the exemplary fifth data collection sub-module 16E illustrated in FIG. 2E, the utility management system 10 includes a remote logger unit 42 that is communicatively coupled to a plurality of utility meters 12 in a wired or wireless manner. For example, the plurality of utility meters 12 can be communicatively coupled to the remote logger unit 42 via Bluetooth, Wi-Fi, other near-field communications, telephone network, Intranet, Internet, Local Area Network (LAN), Ethernet, wireless communications, combinations thereof, and/or the like. The remote logger unit 42 can be programmed to collect the utility usage data from each of the utility meters 12 to which it is coupled on a periodic basis (e.g., every 15 minutes, every 30 minutes, once an hour, etc.) or in real time.

The remote logger unit 42 is further communicatively coupled to the fifth data collection sub-module 16E over an external communications network 22. In the illustrated example, the remote logger unit 42 and the fifth data collection sub-module 16E each include a GSM/GPRS modem for communicating the utility usage data from the remote logger unit 42 to the fifth data collection sub-module 16E over a GSM/GPRS network using a CSV data format. However, it should be understood that, according to additional and/or alternative aspects, the remote logger unit 42 and the fifth data collection sub-module 16E can be configured to communicate over other communications networks 22, according to other communications protocols, and/or using other data formats.

According to some aspects, the remote logger unit 42 can automatically initiate the connection and communication with the fifth data collection sub-module 16E. Such connections can be initiated on a periodic basis (e.g., every hour, every two hours, once a day, once a week, etc.) and/or at set times of the day/week/month (e.g., at 6 am and 7 pm on weekdays). This upload rate can be fixed or selectively determined by the user and/or the host system 14. Advantageously, the upload times and/or frequency can be selected to occur during off-peak times so as to minimize data communication charges.

The fifth data collection sub-module 16E can further include a server 30 for facilitating communication with the remote logger unit 42. The server 30 can be configured to process the utility usage data received from the remote logger unit 42 before storing the utility usage data in the data storage module 18. For example, the files received by the server 30 from the remote logger unit 42 can include aggregated utility usage data for a plurality of utility meters 12 that may need to be parsed and processed so that the utility usage data can be stored in the data storage module 18 in an appropriate manner and format.

According to some aspects, the server of the fifth data collection sub-module 16E can be further configured to manage the remote logger unit 42 by communicating control signals from the server 30 to the remote logger unit 42. That is, the remote logger unit 42 and the server 30 can be configured for bi-directional communication. In this way, the fifth data collection sub-module 16E can be configured to provide firmware upgrades to the remote logger unit 42 in the field and also upload configuration information to the remote logger unit 42 (e.g., meter configuration, polling rates for collecting the utility usage data from the meters, upload rates or times for transmitting the utility usage data from the remote logger unit 42 to the fifth data collection sub-module 16E, etc.).

According to some aspects, the server of the fifth data collection sub-module 16E can be configured to store the files received from the remote logger units 42 in a file directory of a local memory. The server 30 can run an FTP service to allow remote applications to retrieve the files stored in the local memory via an FTP server protocol.

While the remote logger unit 42 is illustrated and described as being communicatively coupled to a plurality of utility meters 12, it is contemplated that the remote logger unit 42 can be communicatively coupled to only a single utility meter 12 in some instances. For example, the remote logger unit 42 can be used to retrofit an existing utility meter 12 that does not have memory and/or is not configured to communicate over a communications network 22.

Again, it should be understood that the data collection sub-modules 16A-16E described and illustrated with respect to FIGS. 2A-2E are intended as non-limiting examples to illustrate how the utility management system 10 can be configured to receive utility usage data from a plurality of different utility meters 12, over different communications networks 22, according to different communications protocols, and/or in different data formats. It should be understood that the exemplary utility management system 10 illustrated and described with respect to FIGS. 1-2E can be modified in various ways consistent with the concepts of the present disclosure (e.g., the first data collection sub-module 16A can be configured to receive utility usage data from non-smart meters). According to aspects of the present disclosure, the utility management system 10 includes two more different data collection sub-modules 16A-16E so as to receive the utility usage data generated by a plurality of different types of utility meters 12.

According to some implementations, the utility usage data can be received by each of the data collection sub-modules 16A-16E according to the same format. According to alternative implementations, the utility usage data can be received in a plurality of different formats by the data collection sub-modules 16A-16E. In such implementations, the data collection module 16 can be configured to process the received utility usage data to convert any non-conforming utility usage data to a uniform or standardized format.

In any event, all utility usage data is received by the data storage module 18 from the data collection module 16 in a consistent and uniform format. The data storage module 18 includes a database 32 for storing the utility usage data received from the data collection module 16. For example, the data storage module 18 can include a database server for providing the database 32. According to one non-limiting implementation, the database 32 can be a relational database such as, for example, a Structured Query Language (SQL) database and/or a big data database such as, for example, Hadoop.

The utility usage data also can be stored in the database 32 with an indication of the time and date that the utility usage data was measured by the utility meters 12 and/or an indication of the source of the utility usage data. For example, the utility usage data can be received and stored in the database 32 with identification information that can be utilized to identify the user associated with the utility usage data, a particular utility meter 12 from which the utility usage data was obtained, a geographic location of the utility meter 12 (e.g., the country, county, city, street address, etc.), a facility in which the utility meter 12 is located, an area within the facility in which the utility meter 12 is located, combinations thereof, and/or the like. Such indications of time/date and/or geographic locations can be utilized by the reporting module 20 to generate various reports, as described in more detail below.

As shown in FIGS. 1-2E, the data reporting module 20 is communicatively coupled to the data storage module 18. The data reporting module 20 is configured to transform the raw utility usage data into meaningful and useful information and display such information to the user of the utility management system 10. According to some aspects of the present disclosure, the data reporting module 20 can include a report server configured to run a business intelligence software application that utilizes the utility usage data stored in the database 32 to provide historical, current, and predictive reports and views of utility usage at the user site. One non-limiting example of a commercially available business information tool is QlikView sold by Qlik Technologies, Inc., which is currently headquartered at 150 N. Radnor Chester Road, Suite E220, Radnor, Pa. 19087. As the report server is communicatively coupled to the database 32 of the data storage module 18 and configured to run the business intelligence software, the reporting module 20 can access the utility usage data stored in the database 32, process the stored utility usage data, and display reports to the user based on the processed utility usage data.

The users of the utility management system 10 can access their particular utility resource usage information via a client computer 44. The client computer 44 can be any suitable data processing and networking device including, but not limited to, a hand-held device, a multiprocessor system, a microprocessor-based or programmable consumer electronic device, a network computer, a minicomputer, a mainframe computer, a net-book, combinations thereof and/or the like. In the illustrated embodiments shown in FIGS. 1-2E, the client computer 44 is a personal computer. The client computer 44 includes a network interface or adaptor (e.g., a modem) for coupling the client computer 44 to a communications network 22 to communicate with the reporting server. In the illustrated examples shown in FIGS. 1-2E, the client computer 44 is configured to communicate with the reporting module 20 via the internet; however, it is contemplated that, according to additional and/or alternative aspects, the client computer 44 can be configured to communicate with the reporting module 20 over other communications networks 22.

The client computer 44 can further include a processor for processing information, a read only memory (ROM) and/or other static storage device for storing static information and instructions to be executed by the processor, and a random access memory (RAM) and/or other dynamic storage device for storing information, temporary variables, and instructions to be executed by the processor. The client computer 44 also includes a display device for displaying information to a user.

The reporting module can be configured to host a website including webpages supporting the utility usage information and reports generated by the business intelligence software. The client computer 44 is operable to run a browser software application that can be integrated with an operating system software, or can be a separate application software. The browser can be a commercially available web browser (e.g., Microsoft Internet Explorer™) or a web client.

Using the browser, a user of the client computer 44 can interactively access and display information and reports based on the utility usage data stored in the database 32. For example, the user can utilize the browser to access the web pages provided by the reporting module 20 over the internet using a browser-readable format, such as hypertext markup language (HTML), and entering the IP address or hostname of the report server into the browser according to a recognized format such as a uniform resource locator (URL) format.

The web pages can be utilized for a variety of purposes. Generally, the web pages displayed by the browser allow the user to interactively select and view text, images, video, audio, and other information included in the web pages. According to some aspects, the web page can include historical, current, or predictive real-time analyses or reports based on the utility usage data stored in the database 32 and the user's interaction with the business intelligence software via the web pages. For example, the web pages displayed in the browser can include graphs, tables, charts, other graphical representations, numerical data, combinations thereof and/or the like that are based on the utility usage data and in response to user selections.

As described above, the utility management systems 10 of the present disclosure can collect, process, and report usage of the utility resources at one or more user sites. According to some aspects of the present disclosure, the one or more user sites can include a plurality of facilities associated with the user, a plurality of areas within a facility associated with the user, and/or a plurality of areas within a plurality of facilities associated with a user. Advantageously, the reporting module 20 is configured to provide utility usage information in a wide variety of formats and varying degree of granularity. For example, the utility usage information can be selectively displayed in graphs, tables, charts, other graphical representations, numerical data on a geographic location basis, a facility-wide basis, a facility area basis, meter basis, a temporal basis, combinations thereof, and/or the like in response to user selections provided to the reporting module 20 via the browser application on the client computer 44.

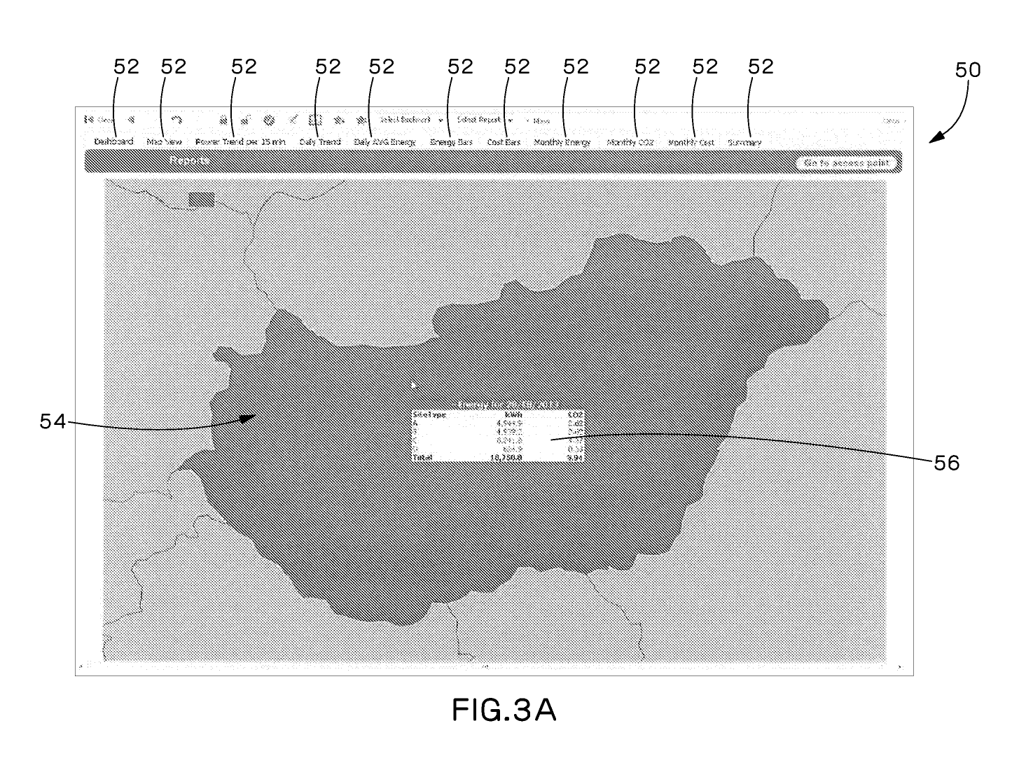

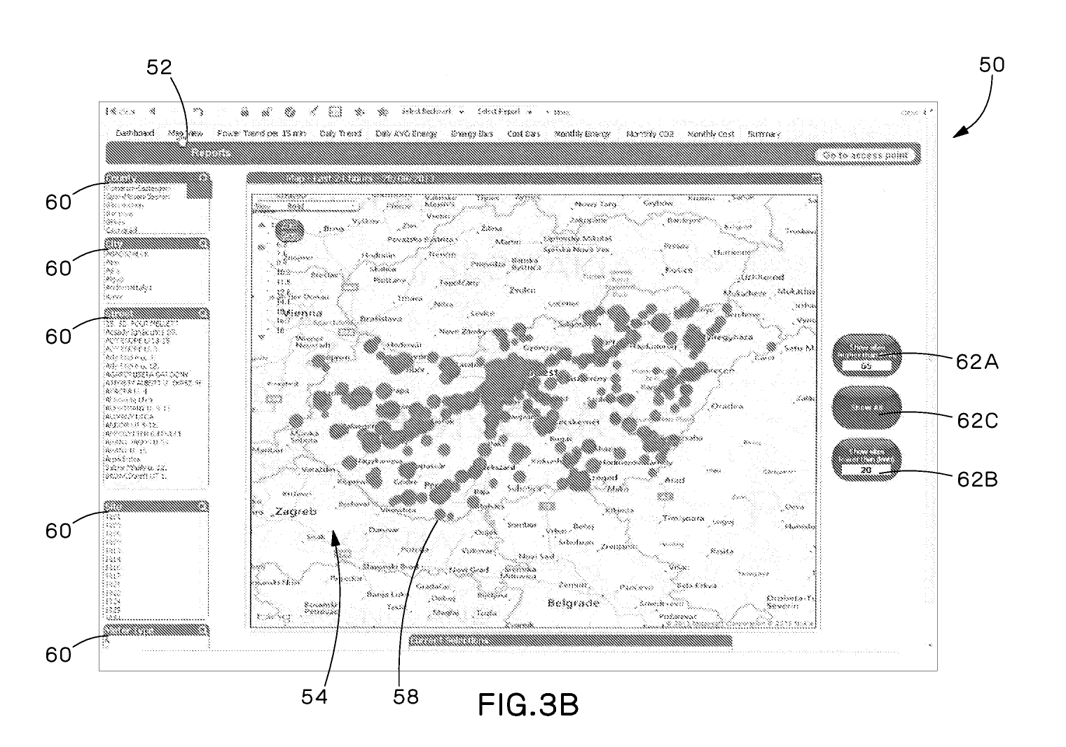

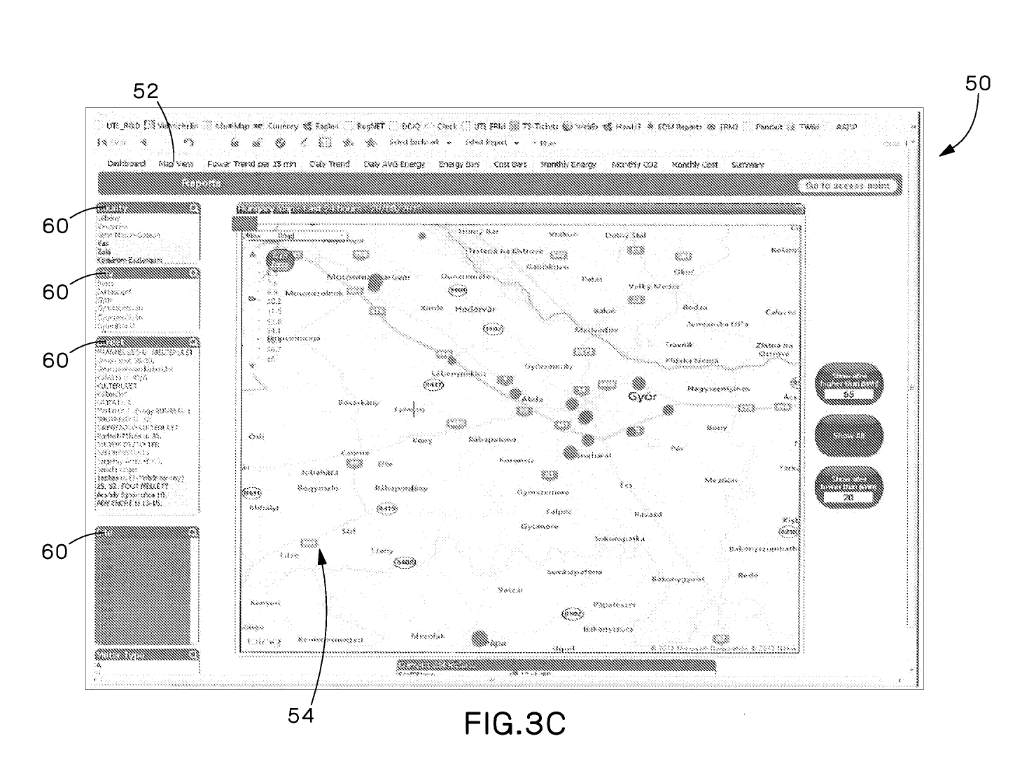

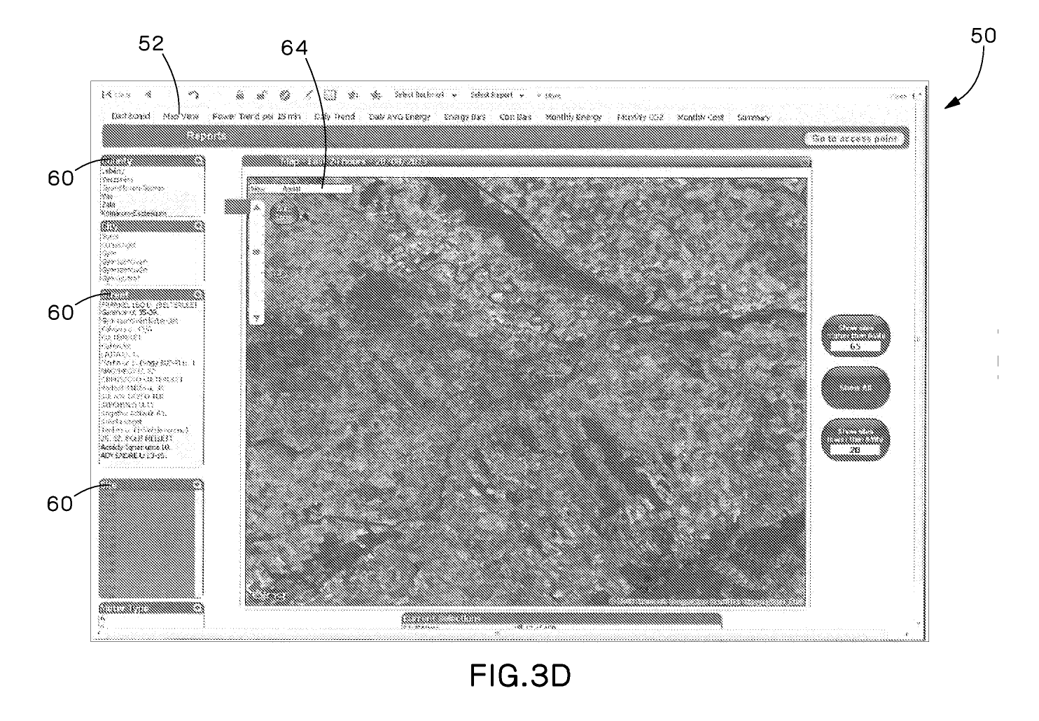

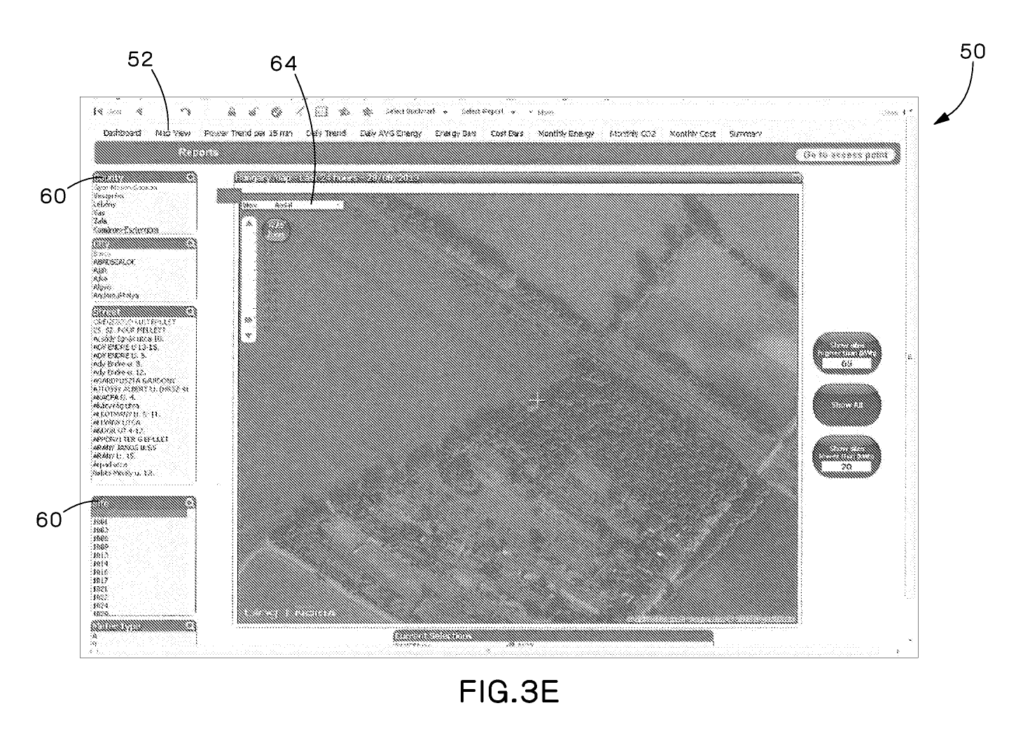

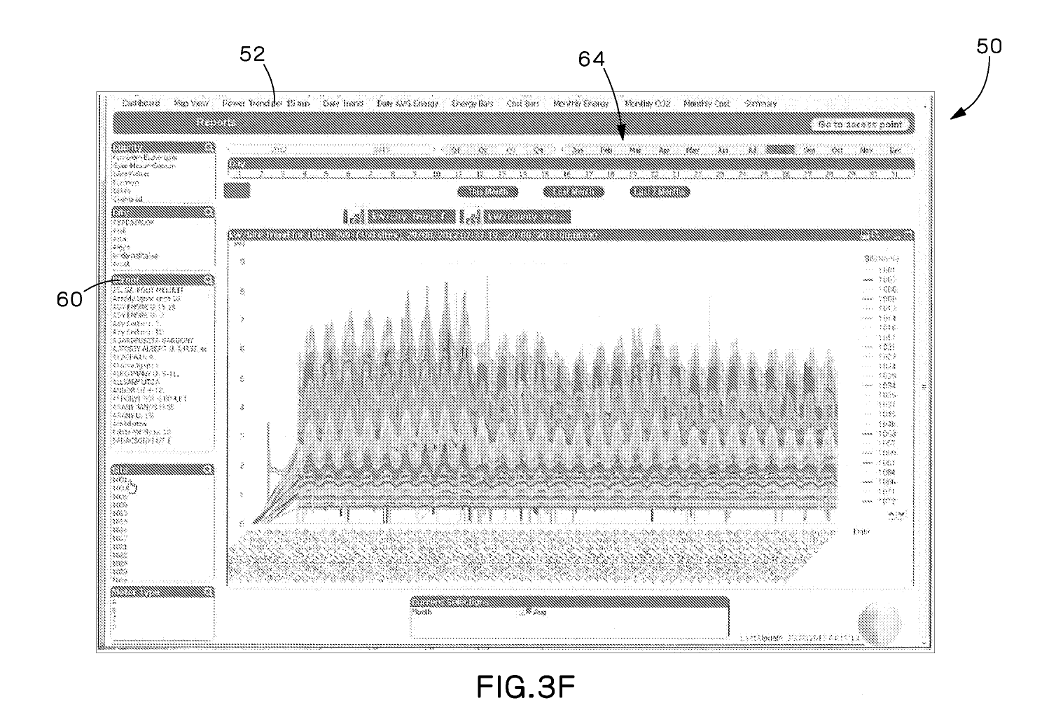

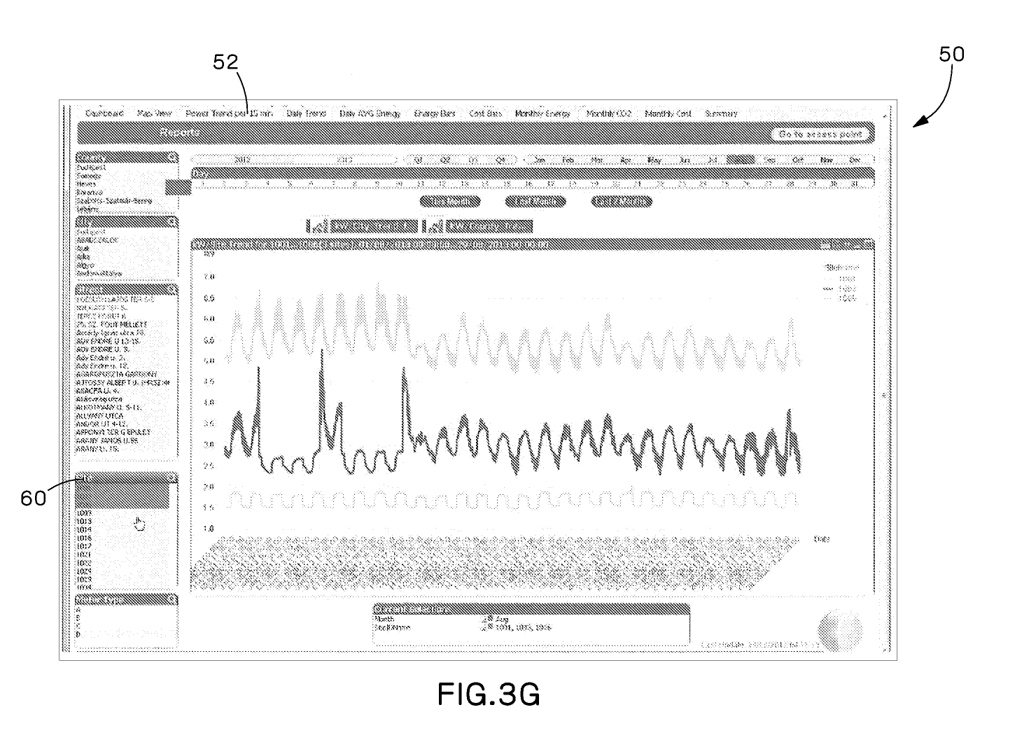

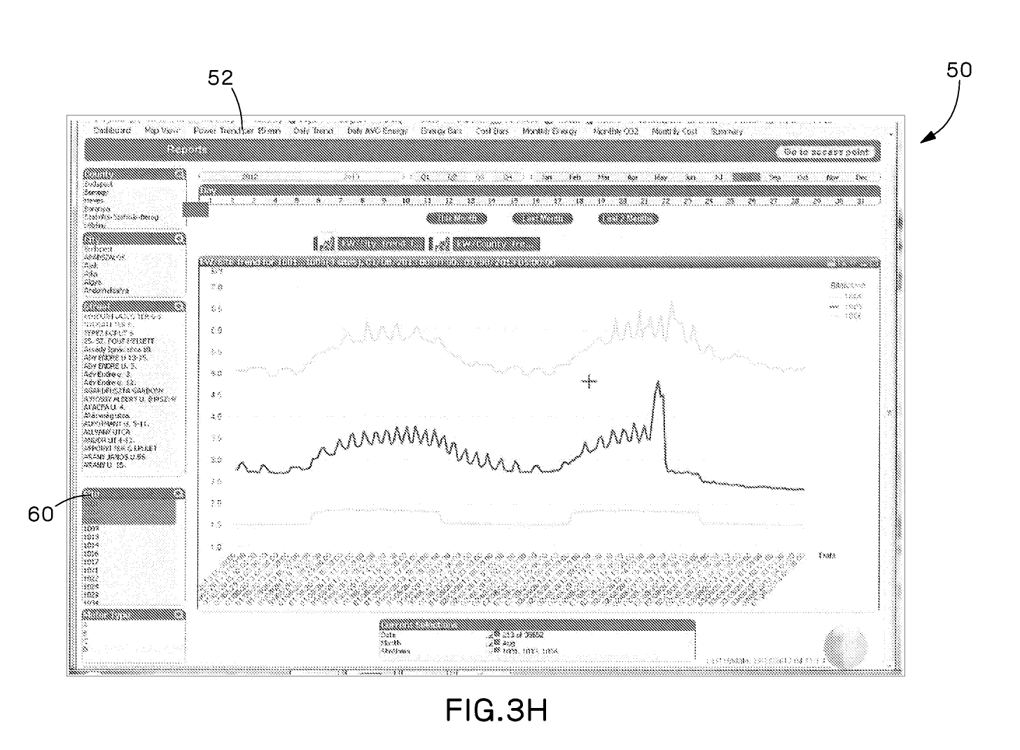

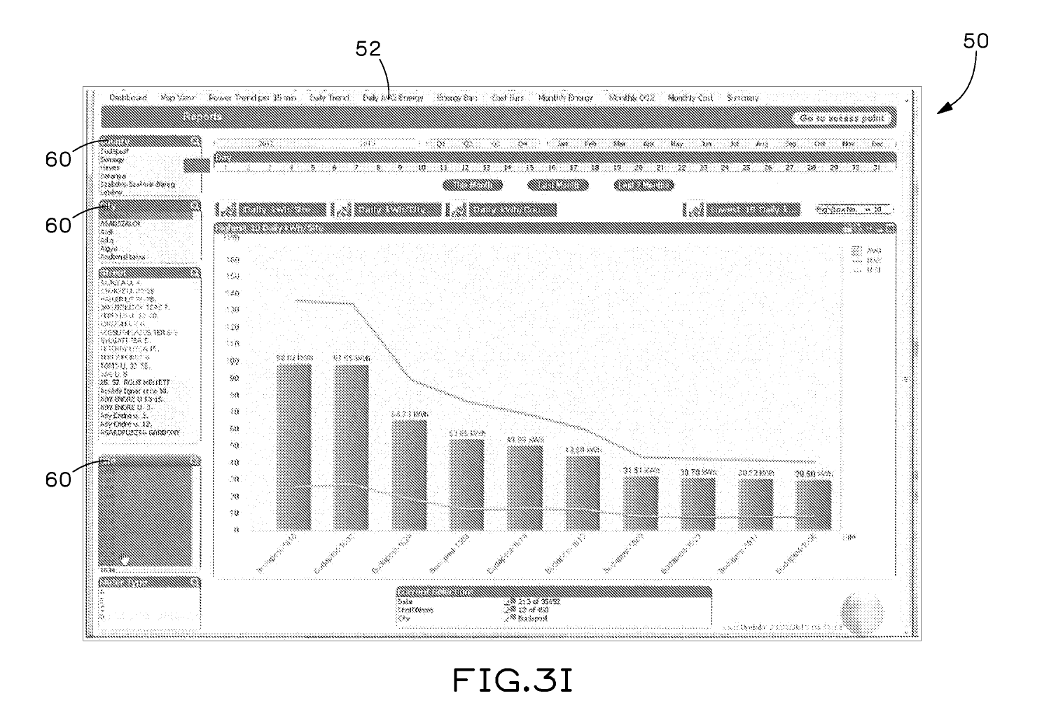

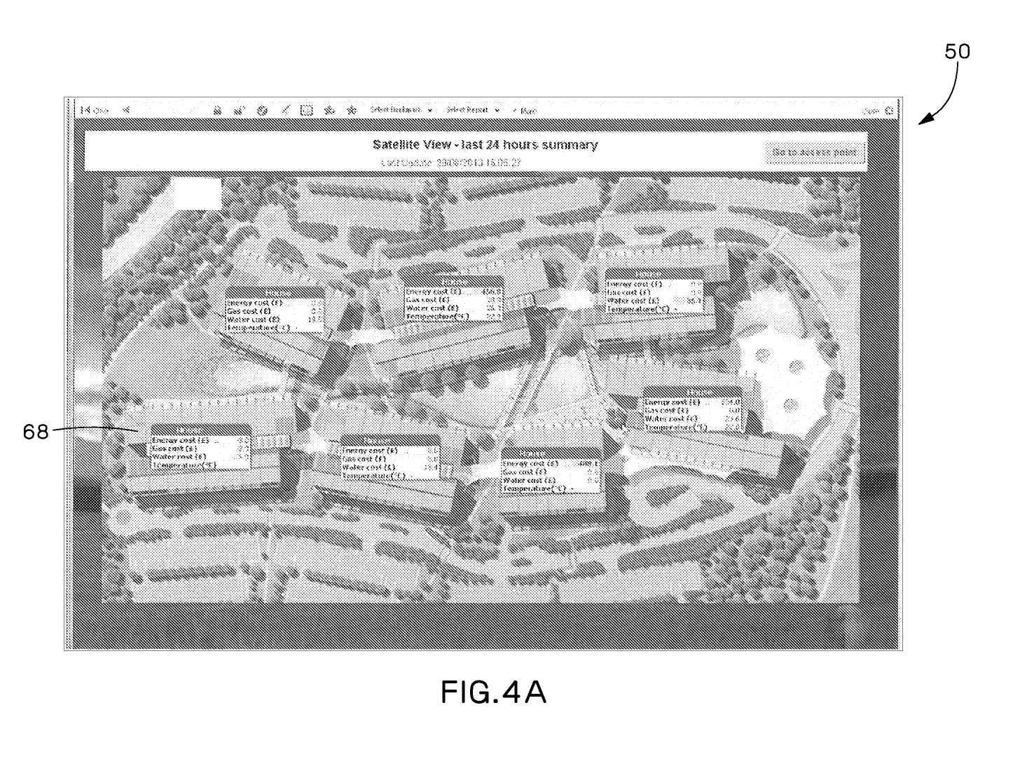

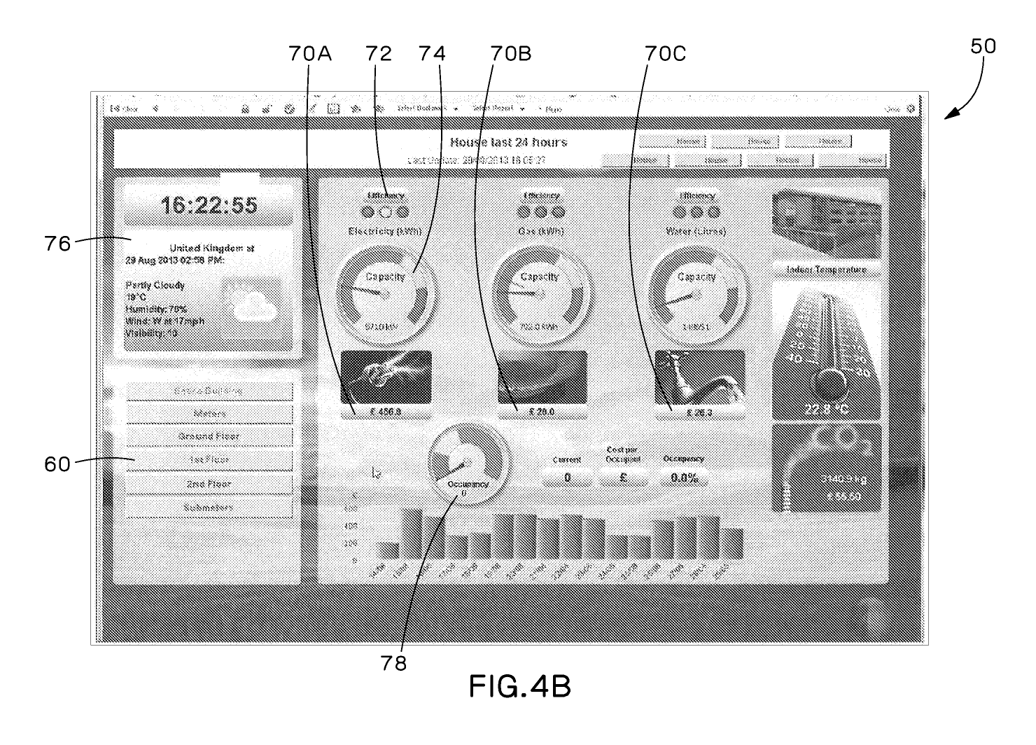

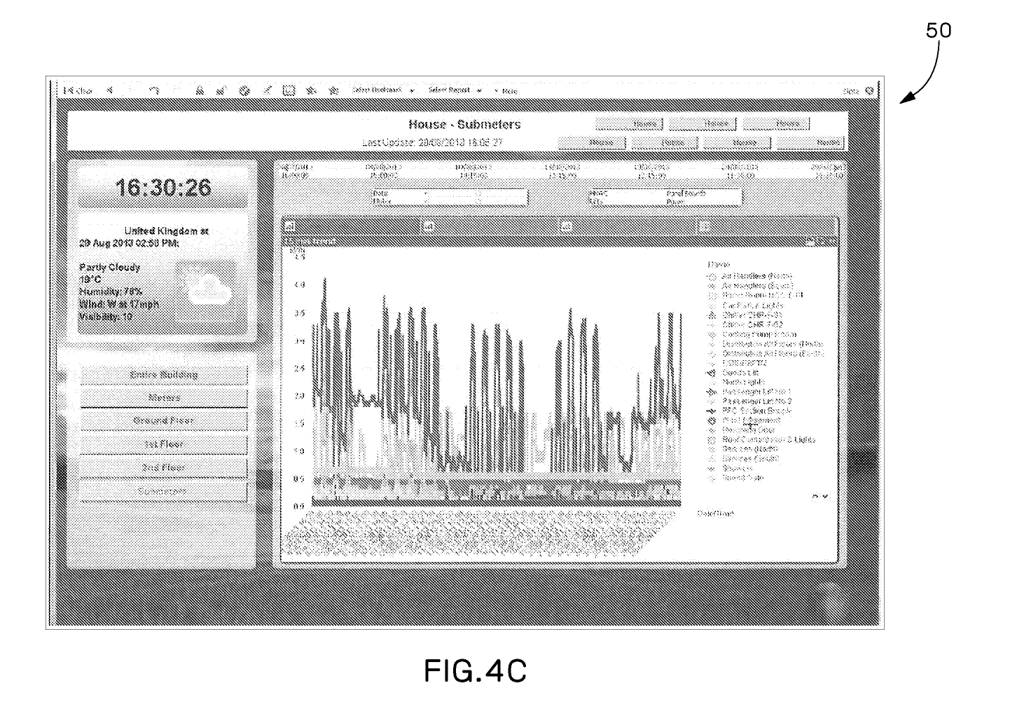

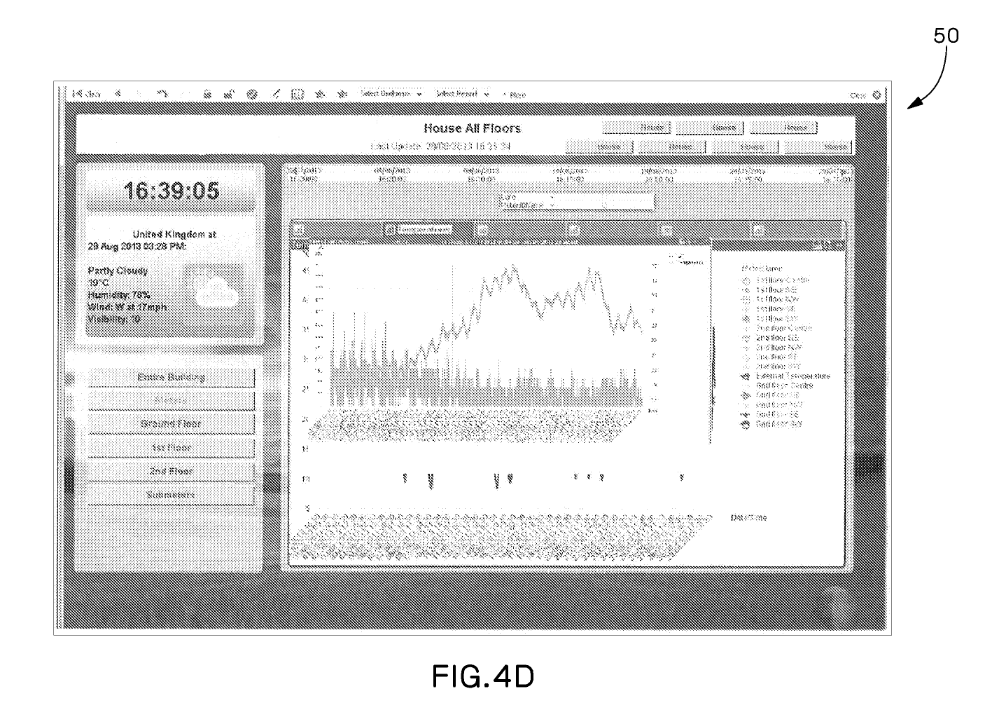

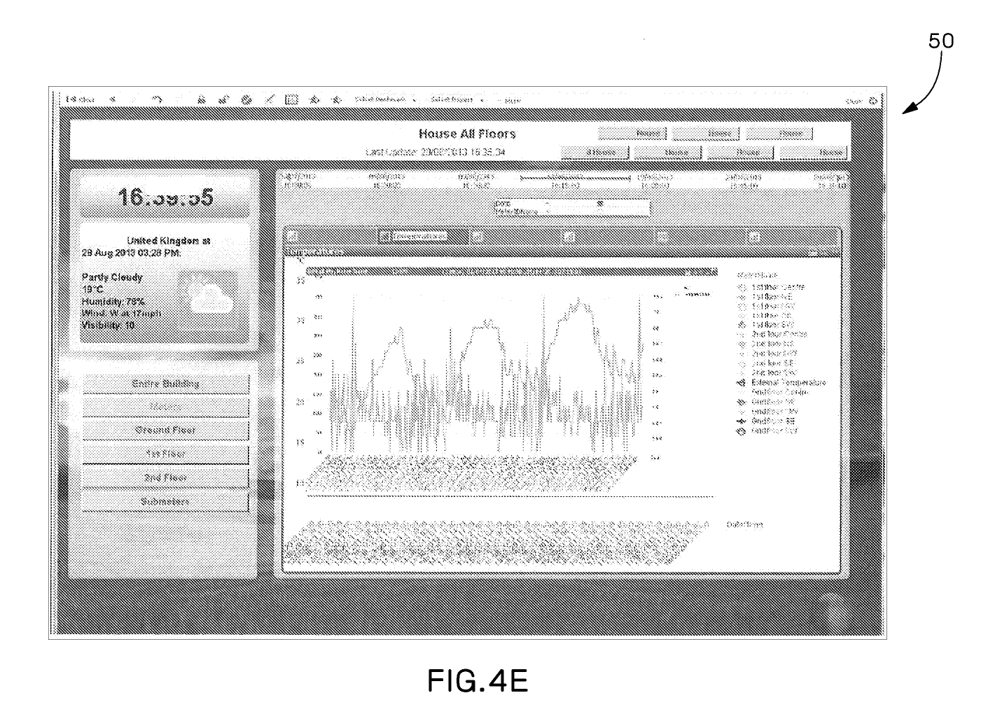

To further describe some aspects of the reporting module 20, a number of screen shots 50 of exemplary web pages that can be provided by the reporting module 20 to the client computer 44 for display to the user are illustrated in FIGS. 3A-4E. Referring to FIGS. 3A-3I, the exemplary screen shots 50 are provided for a user having a plurality of electric utility meters 12 located at a plurality of geographic locations within a country. While the exemplary screen shots 50 of FIGS. 3A-3I provide reports relating only to an electrical utility resource, it should be understood that additional and/or alternative utility resources can be included.

As shown in FIG. 3A, the reporting module 20 can be configured to provide the user with a plurality of selectable options 52 for displaying different reports based on the utility usage data stored in the database 32. In the illustrated example, the selectable options 52 include a dashboard option, a map view option, a power trend per 15 minute time interval option, a daily trend option, a daily average energy usage option, an energy bars option, a monthly energy usage option, a monthly carbon dioxide emission option, a monthly cost option, and a summary option. These options 52 are provided as examples and thus it should be understood that the reporting module 20 can be configured to include all of these options 52, some of these options 52, and/or alternative options 52. The dashboard option, the map view option, the power trend per 15 minute time interval, and the daily average energy options will be illustrated and described below. The reports displayed for the monthly carbon dioxide emission option and monthly cost option can be based not only on the utility usage data stored in the database 32 but also on one or more scaling factors (e.g., a rate for the cost per unit of utility resource or a ratio of unit of utility resource usage to carbon dioxide emission quantity) stored in the database 32 for computing the cost of the utility resource consumption or the amount of carbon dioxide emitted. It is contemplated that the reports can additionally and/or alternatively be based on one or more billing profiles (e.g., costs dependent on the time of day, week, month, year, etc.) and/or one or more demand profiles.

FIG. 3A illustrates an exemplary screen shot 50 for a user selection of the dashboard option, which provides a graphical map 54 of various countries in which the user may have utility meters 12 deployed at user sites. As shown in FIG. 3A, the country of Hungary has been selected by the user (e.g., by clicking on the country of Hungary using a mouse) for information. Once the user selects the country, additional information regarding a utility resource such as, electricity in the illustrated example, can be displayed. For example, in FIG. 3A a table 56 is displayed indicating four different user site types, the energy used at each site type (in kWh), and the amount of carbon dioxide emitted for each site type.

FIG. 3B illustrates an exemplary screen shot 50 for a user selection of the map view option. As shown in FIG. 3B, the reporting module 20 is configured to provide a graphical representation of a geographic map 54 to the user. More particularly, the reporting module 20 provides a graphical representation 58 of the utility resource usage on the geographic map 54 based on the utility usage data stored in the database 32. For example, in FIG. 3B, a graphical representation 58 of utility usage data associated with the user sites is displayed on the map 54 by a circle having a size that corresponds to the amount of the utility resource consumed at the user site within a particular time period (e.g., within the last day in FIG. 3B). Thus, a user site that used less of a utility resource within the time period will be represented on the map 54 by a circle having a smaller diameter than a user site that used a greater amount of a utility resource within the time period. In this way, the user can quickly and easily understand the amount of utility resource consumption at various parts of the country, cities, and/or user sites. It should be understood that, according to additional and/or alternative aspects, other graphical representations 58 of the utility usage data can be utilized such as, for example, other shapes, colors, combinations thereof, and/or the like.

Additionally, the reporting module 20 can be further configured to provide the user with a plurality of selectable inputs 60 to allow the user to control which user sites are displayed on the map 54. In the illustrated example, the plurality of selectable inputs 60 includes inputs for country, city, street address, user site, and meter type. As such, the user can select all, some, or none of the selectable inputs 60 to control whether all, some, or none of the graphical representations 58 of the utility usage data at each user site is displayed on the map 54 to the user.

Further, the reporting module 20 can be configured to provide quick-report buttons 62A-62C that may be selected by the user to further control which graphical representations 58 of user sites are displayed. For example, in the illustrated example, a first quick-report button 62A can be selected by the user to display the graphical representations 58 for the user sites that have utility usage data within the particular time period above an upper threshold, a second quick-report button 62B can be selected by the user to display the graphical representations 58 for the user sites that have utility usage data within the particular time period below a lower threshold, and a third quick-report button 62C that can be selected to display all graphical representations 58 for all user sites.

The reporting module 20 can be further configured to receive user inputs in form of user selections made on the graphical map 54. For example, the user can use an input device (e.g., a mouse) to highlight or select an area on the map 54 to initiate a zoom-in functionality. FIG. 3C illustrates an exemplary screen shot 50 of a web page after a user has zoomed in on a particular geographic area. As shown in FIG. 3C, the user has also utilized the selectable inputs 60 to indicate that only certain street addresses are to be displayed. Thus, the map 54 displays only the graphical representations for the user sites at the selected street addresses within the geographic area selected by the user using the zoom functionality.

According to some aspects, the graphical map 54 can be shown instead using satellite imagery in response to a user selection. For example, FIG. 3D illustrates the map 54 provided in the exemplary screen shot 50 of FIG. 3C after the user has selected a satellite imagery option 64. As another example, FIG. 3E illustrates the map view with the satellite imagery option 64 activated after the user has further zoomed in on a single user site. As shown in FIG. 3D, the ability to use satellite imagery can provide additional information not apparent from a graphical map 54 such as, for example, the type of terrain at the user site, the proximity to different types of geological features (e.g., in a valley, on a mountain, near a river), the proximity to industrial centers, urban areas, rural areas, etc. Such information may be useful in accessing utility resource consumption at the user site.

FIG. 3F illustrates the power trend per 15 minutes option. As shown in FIG. 3E, the power levels over 15 minute intervals based on the utility usage data stored in the database 32 can be graphically displayed for a plurality of user sites over time. Again, the plurality of selectable inputs can be provided to allow the user to control which of the utility usage data is displayed to the user. Additionally, the reporting module 20 can also be configured to allow the user to selectively control the timeframe for which the utility usage data is utilized to generate the reports. For example, in the exemplary screen shot 50 illustrated in FIG. 3B, the user can selectively adjust the timeframe for the data shown in the reports using one or more time inputs 66. This information can be particularly helpful in facilitating user decisions regarding utility resource usage as utility bills are based not only on the total consumption of a utility resource but also on the peak demand within a particular time period. Thus, by continually monitoring the energy consumption, non-critical loads can be shed during times of high energy usage to minimize the peak demand and thus the utility costs.

FIG. 3G illustrates an exemplary screen shot 50 of the power levels over 15 minute intervals after the user has zoomed in on a portion of the graph displayed in FIG. 3F (e.g., using a mouse to select an area on the map 54) and selected only three user sites using the selectable input 60 for user sites. As shown in FIG. 3G, the top and bottom plots on the graph appear to have a relatively uniform distribution over time while the middle plot appears to have a few irregularities indicated by spikes in the middle plot. Using this type of report, the user can identify such irregularities and investigate the causes accordingly. As a non-limiting example to illustrate this point, the user might switch to the map view option, select the user site associated with the middle plot using the selectable option 60 for site or street address, zoom in, activate the satellite mode, and recognize that the user site is located directly next to a football stadium. Based on the times of the irregularity spikes and the proximity of the user site to the football stadium, the user may be able to deduce that an event at the football stadium was the cause of the irregularity spikes. FIG. 3H illustrates yet another graph for the plots shown in FIG. 3G after the user has zoomed in still further on the graph, for example, by selecting an area on the graph using an input device (e.g., a mouse).

FIG. 3I illustrates an exemplary screen shot 50 of a report displayed to the user in response to the user selecting the daily average energy option. As shown in FIG. 3I, the user selected only certain ones of the selectable inputs 60 and thus only the graphic displayed is based on the utility usage data from only those user sites. The graphic displayed provides an indication of the average daily energy consumed at the selected user sites using a bar graph representation. The graphic also displays a lower line plot indicating a minimum energy usage at each user site as well as an upper line plat indicating a maximum energy usage at each user site.

The screen shots illustrated in FIGS. 3A-3I are examples of some reports that can be generated for display to the user by the reporting module 20 where the user has utility meters 12 located at a plurality of different user sites. It should be evident from the above examples that the reporting module 20 can thus provide a wide variety of information to the user based on the utility usage data collected by the utility meters 12 and stored in the database 32. For example, the reports can provide analytics regarding utility resource consumption on an individual meter basis, on a site basis, on a citywide basis, on a county-wide basis, on a country-wide basis, and/or based on the type of meter (e.g., based the type of utility resource monitored by the utility meter 12, based on the data collection sub-module 16A-16E with which the utility meter 12 communicates, etc.). This allows the data to be displayed on a more granular, individual basis or on a high level, aggregated basis. Additionally, for example, the reporting module 20 can report the information based on the utility usage data over user specified timeframes. The utility management system 10 thus provides a versatile tool for obtaining information upon which the user can make more informed and strategic decisions as to its use of utility resources at its facilities.

FIGS. 4A-4E illustrate screen shots 50 of exemplary webpages provided by the reporting module 20 to a client computer 44 for displaying reports based on a user's use of utility resources at a plurality of facilities 68 monitored by a plurality of utility meters 12. FIG. 4A illustrates a graphical representation of the user's facilities 68 including summary information based on the utility usage data obtained within the last 24 hours for each one of the user's facilities. In particular, the exemplary screen shot 50 shown in FIG. 4A indicates the energy cost, gas cost, water cost, and external temperature at each of the areas.

FIG. 4B illustrates another exemplary screen shot 50 for the display of reports relating to one of the user's facility. As shown in FIG. 4B, the reporting module 20 can be configured to provide a graphical indication of the cost associated with each utility resource monitored at the user facility 68. That is, the utility usage data for each utility resource monitored at the facility 68 can be aggregated and processed with corresponding fee rates (i.e., scaling factors) and displayed to the user. For example, FIG. 4B includes an indication of each of the cost of electricity consumed 70A, gas consumed 70B, and water consumed 70C across the entire facility 68. According to some aspects, the reporting module 20 can be further configured to determine and display an indication of the efficiency 72 and capacity 74 associated with each utility resource utilized at the facility 68.

Also shown in FIG. 4B, the reporting module 20 can be configured to provide a plurality of selectable inputs 60 to allow the user to switch between different types of reports. For example, in FIG. 4B, the reporting module 20 is configured to provide selectable inputs 60 allowing the user to switch between a report relating to the entire facility 68, a meters report, a report based on the ground floor of the facility, a report based on the first floor of the facility, and a submeters report. The report shown in FIG. 4B further includes an indication of environmental conditions 76 and occupancy information 78, as further described below.

FIG. 4C illustrates an exemplary screen shot 50 for a report based on the submeters at the user facility 68. As shown, the displayed information based on the utility usage data can be displayed with an identification of the source of the utility usage data (e.g., a utility meter, a device to which the utility meter is coupled, etc.).

Although the data collection module 16 (and the constituent data collection sub-modules 16A-16E) has been described as being configured to collect and process the utility usage data generated by the plurality of utility meters 12, according to additional aspects of the present disclosure, the host system 14 can be configured to receive additional data via the data collection module 16 that can assist in evaluating and managing utility resource usage at the user site.

According to some aspects of the present disclosure, the utility management system 10 can include one or more environmental sensors 80 (see FIG. 2E) configured to monitor environmental conditions at the user site and generate environmental data indicative of the monitored environmental conditions. For example, the one or more environmental sensors 80 can be configured to monitor a temperature, humidity, and/or wind at one or more locations at the user site. Additionally, other environmental data such as, for example, degree day data can be determined based on the monitored environmental conditions and/or imported from a third party via the data collection module 16. According to some aspects, the one or more environmental sensors 80 can include suitable hardware and/or software for communicating the measured environmental data to the data collection module 16. For example, the one or more environmental sensors 80 can include a dial-up modem, a broadband modem, an antenna for communication over a cellular telephone network, etc. for communicating the environmental data to the data collection module 16. According to other aspects, the one or more environmental sensors 80 can be communicatively coupled to a remote logger unit 42 such that the environmental data is first collected by the remote logger unit 42 and then transmitted to the data collection module 16 along with or separately from any utility usage data collected by the remote logger unit 42. The data collection module 16 is configured to process the received environmental data and communicate the processed environmental data to the data storage module 18.

For example, FIG. 4D illustrates a report based on the utility usage data for each of the meters 12 at the user facility graphed along with an indication of the measured external temperature at the corresponding points in time. Such environmental information can thus shed additional light as to why certain utility usage profiles may be exhibited in the reports generated by the reporting module 20 based on the monitored utility usage data. FIG. 4E illustrates an exemplary screen shot 50 for the report shown in FIG. 4D after the user has zoomed in on the graph, for example, using an input device (e.g., a mouse) to select an area of the graph.

According to additional and/or alternative aspects of the present disclosure, the utility management system 10 can include one or more personnel sensors configured to monitor the presence of people at one or more locations within the user site and generate occupancy data indicative of the monitored presence of people at the one or more locations. For example, the one or more personnel sensors can include people counting device(s) at entrances and exits to one or more areas at the user site, motion detector(s), image capture device(s) (e.g., a video camera), combinations thereof, and/or the like.

As another example, the one or more personnel sensors can determine the occupancy of one or more areas of the user site based on electronic devices carried and/or utilized by the people at the user site. In one non-limiting implementation, a user site may be configured such that staff within the building(s) of the user site carry mobile devices such as, for example, mobile telephones, laptops, personal data assistants (PDAs), etc. which are connected to one or more radio nodes in the building(s) of the user site. Such radio node(s) can be wire or wirelessly connected a communications network 22 (e.g., a PSTN network), for example, via a fiber backhaul link. The radio node(s) in conjunction with a system software can monitor how many data links are active at any given time between the mobile devices and each node. One commercially available system that can support this type of infrastructure is currently manufactured and sold by SpiderCloud Wireless, which is currently headquartered at 408 E. Plumeria Drive, San Jose, Calif. 95134.

The information derived from the one or more sensors can used be used to help determine how many staff are in a building and, in some instances, where in the building each staff member is located (e.g., which floor, wing, room, etc.). The one or more personnel sensors can be configured to communicate directly with a sub-module of the data collection module 16 and/or indirectly via an intermediary device such as, for example, a remote logger unit 42 or an FTP server. According to some aspects, the personnel data can be received in the data collection module 16 according to a CSV format. According to other aspects, the data collection module 16 can be configured to process the personnel data to convert it to a standardized data format for storage in the data storage module 18.

By monitoring the occupancy of different areas of a user facility (e.g., different wings, floors, rooms, etc.), the reporting module 20 can determine and display an indication of the energy costs per person for operating the different areas of the user facility. This in turn provides valuable insight to allow the user to make decisions whether and/or how to utilize its facilities to improve efficiency and save costs. For example, in some instances, the user can decide to only activate climate control devices in areas of the facility that are occupied by personnel. As such, the facility can be strategically divided into different areas or segments such that the user can determine whether to activate, deactivate, or otherwise control devices in those areas or segments and/or whether to shut off utility resources provided to particular areas that are not occupied.

It is contemplated that, according to some aspects of the present disclosure, the utility management system 10 can be configured to automatically control various devices at the user facility. For example, the utility management system 10 can be configured to generate and communicate control signals to one or more devices at a user facility so as to control the operation of those devices.

In view of the foregoing, it should be apparent that the utility management systems 10 of the present disclosure provide a number of advantages over prior systems for monitoring a utility resource. The utility management systems 10 of the present disclosure can be configured to incorporate a plurality of different utility meters 12 into one system by providing a plurality of different data collection sub-modules (i.e., different hardware and/or software specifically configured to communicate with the different types of utility meters 12). Moreover, as the utility usage data can be obtained automatically from the utility meters 12 at remote locations relative to the host system 14 with no need for polling, the utility management system 10 can provide a cost effective alternative to prior methods of utility usage data acquisition and processing. In addition to cost reductions, the utility usage data may be acquired more frequently (depending upon a user's preferences), providing more rapid and granular intelligence and eliminating the need for estimated service billing which results when meters are not read at least once every billing cycle.

The utility management systems 10 can also process and store the monitored utility usage data in a uniform and standardized format for facilitating rapid reporting based on the utility usage data. Further, the interactivity of the reporting interface for the user provides new levels of depth and flexibility for analysis of utility usage data. As a result, the utility management systems 10 of the present disclosure allow users to make strategic decisions to improve their level of profitability via intelligent process monitoring and control.

While the present invention has been described with reference to one or more particular embodiments, those skilled in the art will recognize that many changes may be made thereto without departing from the spirit and scope of the present invention. Each of these embodiments and obvious variations thereof is contemplated as falling within the spirit and scope of the invention, which is set forth in the following claims.

What is claimed is:

1. A utilities management system for collecting, processing, and reporting utility usage data received from a plurality of utility meters, the plurality of utility meters being configured to monitor a utility resource at a user site, the utilities management system comprising:
a first data collection device located remotely relative to the user site, the first data collection device being configured to receive the utility usage data from a first utility meter via a first communications network;
a second data collection device located remotely relative to the user site, the second data collection device being configured to receive the utility usage data from a second utility meter via a second communications network, the first communications network being different from the second communications network, the first utility meter being different from the second utility meter;
a database communicatively coupled to the first data collection device and the second data collection device, the database being configured to store the utility usage data received from the first data collection device and the second data collection device on a database server at a remote location relative to the user site; and
a reporting interface configured to permit users to interactively view utility information based on the utility usage data stored in the database.

2. The utilities management system of claim 1, wherein the first utility meter is a smart meter.

3. The utilities management system of claim 2, wherein the first communications network is an internet network, the first data collection device having a first internet protocol (IP) address and the smart meter having a second IP address.

4. The utilities management system of claim 3, wherein the second IP address is dynamically assigned.

5. The utilities management system of claim 3, wherein the utility usage data is received at the first data collection device according to a general packet radio services (GPRS) protocol.

6. The utilities management system of claim 3, wherein the second communications network is a telephone network, the second data collection device includes one or more host dial-up modems configured to receive the utility data from the second utility meter via the telephone network, and the second utility meter includes a device dial-up modem for communication via the telephone network.

7. The utilities management system of claim 3, wherein the second data collection device is a file transfer protocol (FTP) server.

8. The utilities management system of claim 7, wherein the utility usage data from the second utility meter is formatted in a comma separated value format.

9. The utilities management system of claim 7, wherein the second utility meter includes an adapter configured to generate the utility usage data based on a pulse count detected by the adapter.

10. The utilities management system of claim 1, further comprising a remote logger unit located at the user site, the remote logger unit being communicatively coupled to at least two of the plurality of utility meters, the utility usage data generated by the at least two of the plurality of utility meters being received and stored in the remote logger unit, the first data collection device receiving the utility usage data stored in the remote logger unit via the first communications network.

11. The utilities management system of claim 10, wherein the remote logger unit is configured to monitor and record environmental conditions at the user site, the reporting interface being configured to provide a report including an indication of the utility usage data relative to the environmental conditions.

12. The utilities management system of claim 1, wherein the reporting interface is configured to provide access to one or more web pages including information based on the utility usage data.

13. The utilities management system of claim 1, wherein the user site includes at least two different facilities associated with a user of the utilities management system.

14. The utilities management system of claim 1, wherein the first data collection device and the second data collection device are configured to receive the utility usage data automatically without requesting the utility usage data from the first utility meter or the second utility meter.

15. The utilities management system of claim 1, wherein the utility usage data measured by the first utility meter relates to at least one of water, air, gas, electricity, steam, industrial fluid, or industrial gas and the utility usage data measured by the second utility meter relates to a different one of water, air, gas, electricity, steam, industrial fluid, or industrial gas.

16. The utilities management system of claim 1, wherein the reporting interface is configured to provide a report including cost information based on the utility usage information stored in the database and a cost scaling factor stored in the database.

17. The utilities management system of claim 1, further comprising a personnel sensor configured to generate occupancy data based on the presence of personnel at one or more locations within the user site, the reporting interface being configured to generate a report based on the utility usage data and the occupancy data.

18. A method of providing utility usage information to a user, the utility usage information being based on utility data determined by a plurality of utility meters located at a user site, the plurality of utility meters including a plurality of different types of utility meters, the method comprising:
automatically receiving at a host system the utility usage data collected by the plurality of utility meters at a user site, the host system being at a location remote from the user site, a first portion of the utility usage data being received via a first communications network and a second portion of the utility usage data being received via a second communications network, the first communications network being different from the second communications network;
processing the received utility usage data;
storing the processed utility usage data in a database; and
reporting the utility usage information, via a reporting interface, based on one or more interactive selections received from a user.

19. The method of claim 18, further comprising displaying a graphical representation on a geographic map of an amount of utility resources used at the user site based on the utility usage data.

20. The method of claim 19, wherein the graphical representation is displayed with a size on the geographical map that is dependent upon the amount of the utility resources used at the user site.

21. The method of claim 18, further comprising determining the occupancy at the user site.

22. The method of claim 20, further comprising determining a utility cost per person based on the utility usage data and the determined occupancy.

23. The method of claim 20, further comprising determining an amount of a utility resource used per person over a period of time based on the utility usage data and the determined occupancy.

24. The method of claim 22, further comprising controlling one or more devices at the user site to reduce the use of the utility resource in response to the amount being greater than a predetermined threshold value.

25. The method of claim 23, wherein the one or more devices are controlled via a control signal communicated from the host system to the one or more devices.

26. A utilities management system for collecting, processing, and reporting utility usage data received from a plurality of utility meters, the plurality of utility meters being configured to monitor a utility resource at a user site, the utilities management system comprising:
a personnel sensor configured to monitor and generate occupancy data based on the presence of personnel at one or more locations within the user site;
a data collection module located remotely relative to the user site, the data collection device being configured to receive the utility usage data from the plurality of utility meters and the occupancy data from the personnel sensor via at least one communications network;
a data storage module communicatively coupled to the data collection module, the data storage module being configured to store the utility usage data and the occupancy data received from the data collection module; and
a reporting module configured to permit users to interactively view one or more reports based on the utility usage data and the occupancy data.
